(19) United States
(12) Patent Application Publication
(10) Pub. No.: US 2026/0215260 A1
(43) Pub. Date: Jul. 23, 2026

(54) FLEXIBLE HEATSINK INTERFACE

(71) Applicant: Applied Materials, Inc., Santa Clara, CA (US)

(72) Inventors: Itai Leshniak, Sunnyvale, CA (US); Subramani Kengeri, Saratoga, CA (US)

(73) Assignee: Applied Materials, Inc., Santa Clara, CA (US)

(21) Appl. No.: 19/035,016

(22) Filed: Jan. 23, 2025

(51) Int. Cl. H01L 23/367; H01L 23/00; H01L 23/373; H01L 23/473; H01L 25/00; H01L 25/07

(52) U.S. Cl. CPC H10W 40/22; H10W 40/255; H10W 40/47; H10W 90/00; H10W 90/734

(57) ABSTRACT

Multi-die packages may include a cover or lid that is placed over vertical stacks of silicon dies. This lid connects to a cooling system or heatsink to dissipate heat away from the dies. However, as thermal expansion/contraction occurs, the dies may lose contact with the cover and heat may build up within the cover around the dies. To solve this problem, a cover may include a flexible membrane on the bottom surface of the cover. The flexible membrane may create an internal cavity filled with a pressurized thermally conductive liquid. The liquid may cause the flexible membrane to expand and conform to a profile of the dies as they move due to temperature changes. The flexible membrane ensures that a thermally conductive pathway is maintained between the cover and the dies to effectively dissipate heat away from the dies.

### TECHNICAL FIELD

This disclosure generally relates heat sinks for integrated circuit packages. More specifically this disclosure describes heat sink designs with a flexible membrane interface with the integrated circuits.

### BACKGROUND

Rapid advancements in semiconductor technology have led to the widespread adoption of multi-die packages, where multiple semiconductor dies are integrated into a single package to enhance performance, functionality, and power efficiency. This design, while advantageous, introduces significant thermal challenges. Heat generated by the densely packed dies can cause thermal hotspots, uneven temperature distributions, and thermal-induced performance degradation, making effective heat dissipation a critical consideration in multi-die package design. Traditional heatsinks and thermal management techniques often struggle to address these issues comprehensively, especially when dies with varying thermal profiles are involved.

### SUMMARY

In some embodiments, a die package may include a substrate, a plurality of dies mounted to the substrate, and a cover placed over the plurality of dies on the substrate. The cover may include a flexible membrane that is configured to deform to conform to a profile of the plurality of dies when placed over the plurality of dies.

In some embodiments, a die package may include a substrate, a plurality of dies mounted to the substrate, and a cold plate that interfaces with a liquid cooling system. The liquid cooling system may be configured to pump a pressurized liquid through the cold plate. The cold plate may include a flexible membrane. The pressurized liquid may cause the flexible membrane to deform to contact the plurality of dies when the cold plate is installed above the plurality of dies.

In some embodiments, a method of assembling a die package may include mounting a plurality of dies to a substrate. The method may also include installing a cover over the plurality of dies on the substrate, wherein the cover comprises a flexible membrane. The method may further include providing a liquid to the cover. The liquid may have a pressure sufficient to cause the flexible membrane to flex and contact the plurality of dies.

In any embodiments, any and all of the following features may be implemented in any combination and without limitation. The cover may include a lid that is mounted to the substrate and covers the plurality of dies on the substrate, and the flexible membrane may be located on a bottom surface of the cover adjacent to the plurality of dies. The cover may include a heatsink that is an integrated part of the cover or is thermally coupled to the cover to dissipate heat absorbed by the cover from the plurality of dies. The plurality of dies may be adhered to the flexible membrane using an adhesive, such that when the plurality of dies or the cover expands or contracts due to temperature changes, the flexible membrane may remain in contact with the plurality of dies through the adhesive. The plurality of dies may be mounted to the substrate such that the plurality of dies are not all a same height from the substrate. The flexible membrane may be configured to flex at least 200 μm at a center of the flexible membrane. The flexible membrane may have a thickness of between 10 μm and 50 μm. The cover may include an internal cavity that is filled with liquid, where the liquid may be pressurized to cause the flexible membrane to deform to conform to the profile of the plurality of dies. The liquid may include a liquid metal. The cover may be a cold plate that includes an inlet and an outlet for circulating the pressurized liquid from the liquid cooling system. The flexible membrane may be formed from carbon fiber. The flexible membrane may be formed from aluminum. The cold plate may include an internal cavity, and the internal cavity may include a plurality of fins mounted on the flexible membrane extending away from the flexible membrane into the internal cavity. The pressurized liquid may cause the flexible membrane to be displaced at least 100 μm at a center of the flexible membrane. The liquid may be provided by a liquid cooling system by circulating the liquid through an inlet and an outlet in the cover, and the pressure of the liquid may be adjustable to cause the flexible membrane to flex and contact the plurality of dies. The liquid may be statically enclosed in an internal cavity of the cover. A heatsink may be mounted to the cover, and the substrate may be mounted to a printed circuit board. The liquid may be pressurized at or above a surrounding atmospheric pressure.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a multi-die package, according to some embodiments.

FIG. 2 illustrates a multi-die package with a heatsink or cold plate used to dissipate heat from the silicon dies, according to some embodiments.

FIGS. 3A-3C illustrate thermal movement that may result in a loss of thermal conductivity between the dies and the cover, according to some embodiments.

FIG. 4 illustrates a multi-die package that uses a cover with a flexible membrane, according to some embodiments.

FIG. 5 illustrates a multi-die package with a cover comprising a cold plate that interfaces with a liquid cooling system, according to some embodiments.

FIG. 6 illustrates a plurality of fins mounted on the flexible membrane to improve heat dissipation, according to some embodiments.

FIG. 7 illustrates a magnified view of the flexible membrane, according to some embodiments.

FIG. 8 illustrates a magnified view of the flexible membrane as it deforms to conform to the profile of the dies, according to some embodiments.

FIG. 9 illustrates a method of assembling a multi-die package, according to some embodiments.

### DETAILED DESCRIPTION

Multi-die packages may include a cover or lid that is placed over vertical stacks of silicon dies. This lid connects to a cooling system or heatsink to dissipate heat away from the dies. However, as thermal expansion/contraction occurs, the dies may lose contact with the cover and heat may build up within the cover around the dies. To solve this problem, a cover may include a flexible membrane on the bottom surface of the cover. The flexible membrane may create an internal cavity filled with a pressurized thermally conductive liquid. The liquid may cause the flexible membrane to expand and conform to a profile of the dies as they move due to temperature changes. The flexible membrane ensures that a thermally conductive pathway is maintained between the cover and the dies to effectively dissipate heat away from the dies.

As traditional monolithic-based designs become increasingly more expensive to manufacture, chiplets have emerged as a successful alternative in system architectures to improve yields, reduce the cost of manufacture, and improve the modularity of designs. Generally, a chiplet is not a package type, but is rather part of a packaging architecture. Each chiplet may include a separate die manufactured from a silicon wafer. Instead of forcing all the functionality of the system (e.g., the central processing unit (CPU), the memory, the graphic processing unit (GPU), various peripherals, etc.) to be manufactured on one large monolithic die, chiplet-based systems separate these functionalities out into separate dies that can then be packaged together to perform the same functionality. By making individual dies smaller, the yield and manufacturing costs are reduced for the overall system.

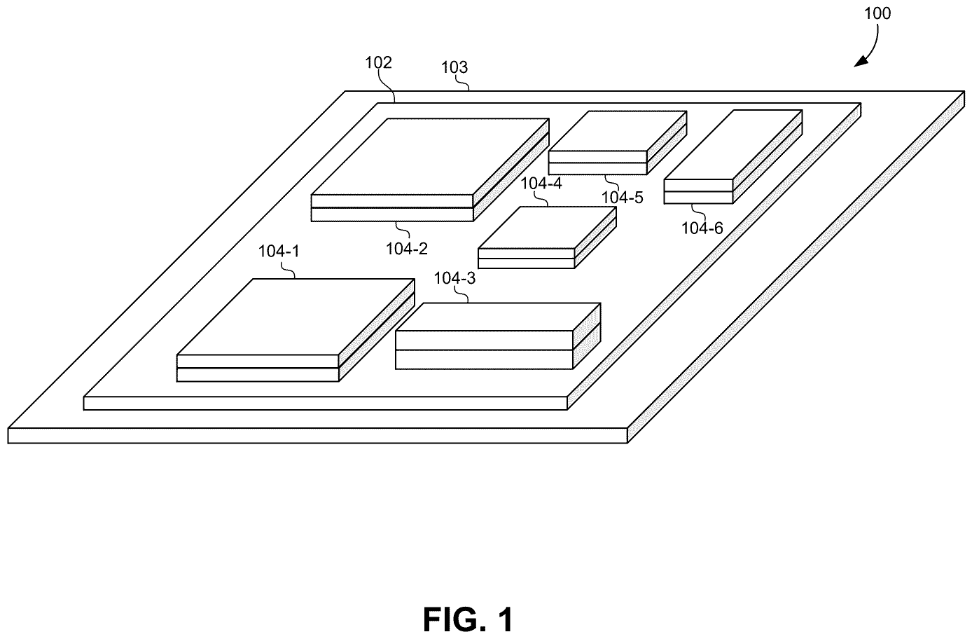

FIG. 1 illustrates a multi-die package 100, according to some embodiments. A plurality of dies 104 may be manufactured as separate dies from one or more silicon wafers. The plurality of dies 104 may be mounted onto a substrate 102, which may form the structure of the multi-die package 100. A printed circuit board (PCB) 103 may form the communication backbone of a system, which may include one or more multi-die packages, even though only a single multi-die package 100 is illustrated in FIG. 1.

The dies 104 may implement a plurality of different functions, such as application-specific systems-on-a-chip (SOCs), a graphics processing unit (GPU), a digital signal processor (DSP), an artificial intelligence (AI) accelerator, various codecs, Wi-Fi communication modules, memory controllers, caches, input/output (I/O) peripherals, high-bandwidth memories (HBMs), and so forth. Although manufactured on separate wafers, each of these dies 104 may be connected together using various options through the substrate 102 to perform substantially the same functions as would be performed by a similar monolithic design, but in a distributed manner.

As illustrated in FIG. 1, semiconductor dies may be mounted vertically on top of each other in a die stacking or 3D stacking configuration. For example, through-silicon vias (TSVs) may allow vertical electrical connections to pass through the silicon dies and provide low-latency communication between the stacked dies. In chiplet-based designs, logic dies such as CPUs and GPUs may be stacked with heterogeneous components such as memory and communication chips. As described below, HBMs may be stacked with other memory dies and/or processor dies in a vertical configuration to achieve higher densities and improved performance.

These vertically stacked dies save space and reduce communication latency. Rapid advancements in semiconductor technology have led to the widespread adoption of these multi-die packages, such as chiplet-based designs, where multiple semiconductor dies are integrated into a single package to enhance performance, functionality, and power efficiency. This design, while advantageous, introduces significant thermal challenges. Heat generated by the densely packed dies can cause thermal hotspots, uneven temperature distributions, and thermal-induced performance degradation, making effective heat dissipation a critical consideration in multi-die package design. Traditional heatsinks and thermal management techniques often struggle to address these issues comprehensively, especially when dies with varying thermal profiles are involved.

To address these challenges, heatsinks and package lids have evolved into integral components of thermal management systems in multi-die packages. A heatsink, typically mounted above the package lid, serves to dissipate heat into the surrounding air through conduction and convection. The package lid, on the other hand, plays a dual role: providing mechanical protection to the underlying dies and acting as a thermal interface. However, achieving efficient thermal coupling between the lid, dies, and heatsink is often constrained by design limitations such as die height variations, non-uniform heat generation, and interface thermal resistance. These limitations hinder the overall effectiveness of traditional cooling solutions.

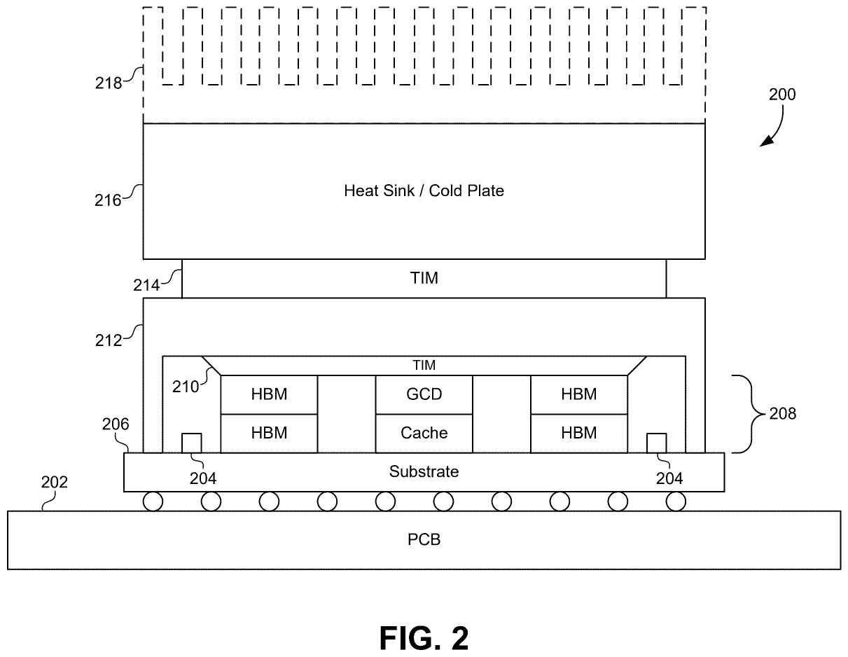

FIG. 2 illustrates a multi-die package 200 with a heatsink or cold plate used to dissipate heat from the silicon dies, according to some embodiments. Maintaining a thermally conductive connection between the silicon dies and the heatsink represents a critical technical challenge in multi-die packages. The multi-die package 200 may be mounted to a substrate 206. The substrate 206 may include any type of substrate, including silicon, silicon carbide, gallium nitride, germanium, quartz, organic materials, glass, and/or other suitable materials. The substrate 206 may be mounted to a PCB 202. The PCB 202 may include additional multi-die packages that are not explicitly shown in FIG. 2 for the sake of clarity. The PCB 202 may facilitate communication between the various multi-die packages and/or between these packages and other external systems.

The substrate 206 may facilitate communication between, and power delivery to the various dies that are part of the multi-die package 200. As described above, a plurality of dies 208 may be mounted to the substrate 206. In some embodiments, the plurality of dies 208 may be vertically stacked, with multiple dies stacked on top of each other in a vertical configuration. For example, HBMs may be vertically stacked on top of each other. Processors, such as a GPU or a graphics compute die (GCD) may be stacked with memory caches. However, vertical stacking is optional and is not required. Some embodiments may use dies that are not vertically stacked or a combination of single dies and vertically stacked dies. The substrate 206 may also include other board-level components that are not necessarily vertically stacked, including capacitors 204 and other discrete circuits.

In order to protect the dies 208 and to create a thermally conductive connection with the dies 208, the multi-die package 200 may include a cover 212. The cover 212 may include a lid that is mounted to the substrate 206 and that covers the plurality of dies 208 on the substrate 206. The cover 212 may include a heatsink that is mounted directly to the tops of the dies 208. The heatsink may be an integrated part of the cover 212 (e.g., the cover 212 and the heatsink may be formed from a single piece of conductive material). Alternatively, a separate heatsink 216 may be thermally coupled to the cover 212 as illustrated in FIG. 2. For example, the heatsink 216 may be adhered to the top of the cover 212 using a thermal interface material (TIM), such as a thermal paste. As used herein, TIMs may include any material designed to enhance heat transfer between two surfaces, such as between the cover 212 and the heatsink 216. Types of TIMs may include preformed solid pads, such as silicone or polymer infused with thermally conductive pillars, adhesive tapes with thermally conductive properties that bond the two surfaces together, metallic alloys, phase change materials that melt at higher temperatures to fill gaps between the two surfaces, graphite pads, epoxies, and so forth. In some embodiments, the heatsink 260 may include a heat dissipating surface 218, such as fins or other geometries configured to radiate heat into the surrounding environment away from the heatsink 216.

In order to transfer heat away from the dies 208, the cover 212 may be thermally coupled to the tops of the dies 208. As used herein, the terms thermally conductive or thermally coupled refers to two objects being connected in a way that allows efficient heat transfer between the two objects. For example, a thermally conductive connection or a thermal coupling may result in less than about 5° C./W, less than about 1° C./W, less than about 0.5° C./W, or less than about 0.1° C./W, depending on the particular embodiment. To achieve an efficient thermal coupling between the cover 212 and the dies 208, a TIM 210 may be applied to the bottom of the cover 212 to interface with the dies 208. While in physical contact with the dies 208, the TIM 210 may transfer heat away from the dies through the cover 212 and out to the heatsink 216.

However, maintaining a thermally conductive contact between the cover 212 and the dies 208 represents a significant technical challenge. With a multi-die package 200, there are multiple different types of materials that are used for the substrate 206, the cover 212, and each of the dies 208. Each of these different materials may have a different coefficient of thermal expansion, resulting in different expansion rates as the multi-die package 200 undergoes changes in temperature. As the processing power increases, the wattage and heat generation increases in a corresponding fashion. This increased temperature during operation may cause the cover to expand or warp in a different direction and/or at a different rate in comparison to the dies 208 and/or the substrate 206. Since each of these materials expands, contracts, and/or warps differently during temperature changes, this often results in a physical separation of the dies 208 from the TIM 210 and the cover 212. Since air is a very inefficient thermal conductor, the resulting air gap between the dies 208 and the TIM 210 or cover 212 greatly increases the thermal resistance and may effectively trap heat within the cover 212 instead of transferring the heat to the heatsink 216.

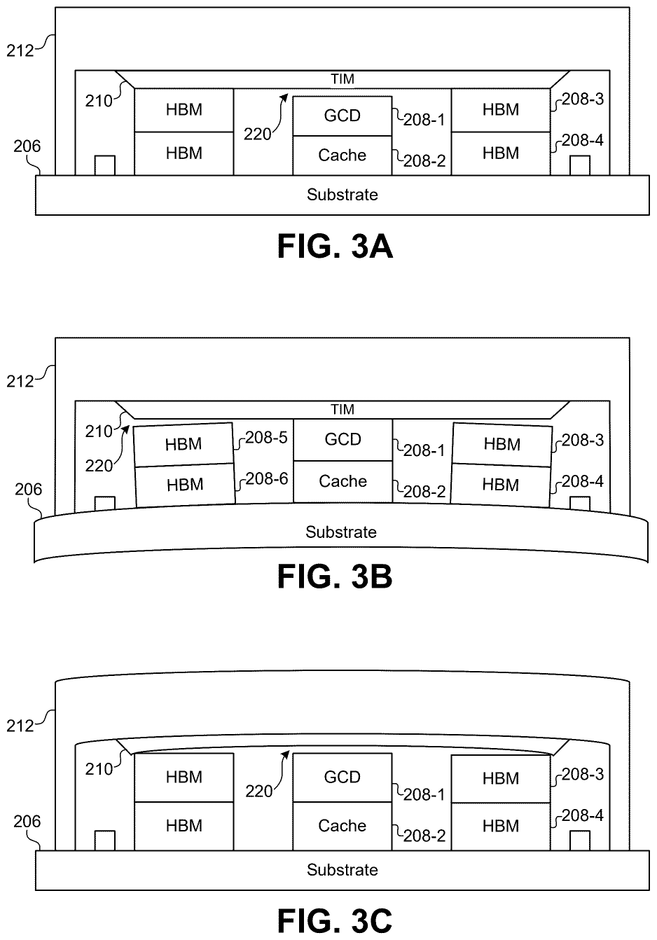

FIGS. 3A-3C illustrate thermal movement that may result in a loss of thermal conductivity between the dies 208 and the cover 212, according to some embodiments. Specifically, FIG. 3A illustrates how an expansion or contraction of the silicon dies 208 may result in a separation from the TIM 210 and the cover 212. For example some dies may expand more and/or faster than other dies resulting in dies stacks that have different heights. When the dies stacks have different heights, a TIM 210 with a uniform thickness may lose contact with one or more of these dies stacks. Note that the different heights of the die stacks may also result from variation within the manufacturing tolerances of these die packages. For example, solder connections between the individual dies in the die stacks may not be consistent throughout the multi-die package. Dies 208-1 and 208-2 may also include slightly thinner packages than dies 208-3 and 208-4. This may result in a die stack that is shorter than others in the multi-die package. Thus, even without the complications of thermal expansion, manufacturing and die variations may cause die stacks with different heights, resulting in a thermal disconnection from the TIM 210 and the cover 212.

FIG. 3B illustrates how a substrate may expand or warp during temperature changes to cause a thermal disconnection between the dies 208 and the TIM 210, according to some embodiments. A bow in the substrate 206 may cause certain areas of the substrate 206 to move closer to the cover 212 or farther away from the cover 212. For example, the die stack including dies 208-1 and 208-2 may be pushed closer to the cover 212, while the die stack including dies 208-3 and 208-4 and the die stack including dies 208-5 and 208-6 may lose contact with the TIM 210 due to warping of the substrate 206.

FIG. 3C illustrates how the cover 212 may expand, contract, or warp during temperature changes to cause a thermal disconnection between the dies 208 and the TIM 210, according to some embodiments. If a thermal expansion causes the cover 212 to bow upwards in the center of the cover 212, the die stack including dies 208-1 and 208-2 may lose contact with the TIM 210.

The examples of FIGS. 3A-3C are only provided by way of example and are not meant to be limiting. Note that thermal expansion may cause many different types of movement by various components in the multi-die package that are not explicitly shown in these figures. In short, any thermal expansion and/or any mismatch of the materials having various coefficients of thermal expansion may cause a separation to occur between the dies 208 and the TIM 210 or cover 212.

In order to solve this technical problem and to provide other technical benefits, the embodiments described herein may use a cover that is placed over the dies on the substrate that includes a flexible membrane configured to deform or flex to conform to a profile of the dies. This flexible membrane on the bottom of the cover allows for die stacks of different heights to maintain thermal contact with the cover. The flexible membrane may be dynamically flexible during use such that physical expansion, contraction, and/or warpage of various components need not cause a gap to form between the cover and the dies. Instead, the flexible membrane may allow the dies to move laterally and/or vertically relative to the cover (or vice versa) while maintaining a thermal connection with the flexible membrane. The flexible membrane may thus move with the dies as the dies or other components move in response to thermal changes in the system.

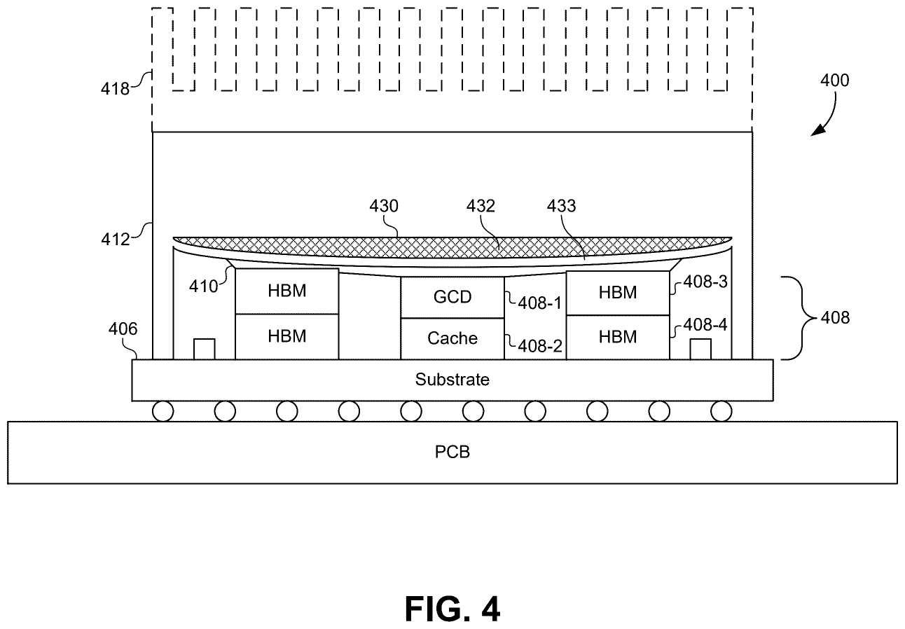

FIG. 4 illustrates a multi-die package 400 that uses a cover with a flexible membrane 433, according to some embodiments. The cover 412 may be mounted to the substrate 406. The cover 412 may completely cover a plurality of dies 408 that fit within a cavity formed within the cover 412. In some cases, the cover 412 may form a hermetic seal around the plurality of dies 408. Although not shown in FIG. 4, encapsulation (e.g., epoxy) may fill an area surrounding the dies 408 to strengthen and protect the area around the dies 408. Although a plurality of dies 408 is illustrated in FIG. 4, other embodiments may include only a single die beneath the cover 412. The flexible interface described below may also be used with a single die instead of a plurality of dies 408 without limitation.

The cover 412 may include an internal cavity 430. The internal cavity 430 may be filled with a liquid 432. The liquid may be thermally conductive to facilitate efficient heat transfer through the liquid. For example, the liquid may include a liquid metal, such as gallium or other metals that may be liquid at operating temperatures (i.e., a melting point at or within 25° C. of standard room temperature). Example materials may include gallium alloys, indium, tin, zinc, and so forth. Other nonmetal, low-melting point materials may also be used, such as diamond powder, carbon nanotubes, carbon nanorods, and so forth. The internal cavity 430 may be formed between a body of the cover 412 and a flexible membrane 433. Therefore, the liquid may fill the space between the body of the cover 412 and the flexible membrane 433. The multi-die package 400 may range in size such that the cover 412 is between about 10 mm×10 mm to about 120 mm×120 mm.

The flexible membrane 433 may be formed from a relatively thin layer of flexible material, such as aluminum, copper, or other metal materials. The flexible membrane 433 may be located on the bottom side of the cover 412 so as to be adjacent to the dies. Other embodiments may use a flexible sheet of carbon fiber that may be coupled to the bottom side of the cover 412. The flexible membrane 433 may be also be formed from other carbon-based material, such as graphite or graphene. Different elastomers may also be used for the flexible membrane 433. The liquid 432 may be pumped into the internal cavity 430 to a pressure that is greater than the atmospheric pressure. For example, the liquid 432 may have a pressure within the internal cavity 430 sufficient to cause the flexible membrane 433 to flex towards the dies 408. This flexation may cause the flexible membrane 433 to conform to a profile of the dies 408. For example, the flexible membrane 433 may flex and expand downward to contact the different heights and/or locations of the plurality of dies 408. Since the internal cavity 430 is filled with liquid 432, this may exert a flexible pressure against the tops of the dies 408 continuously as the dies 408 and/or other components thermally expand, contract, and/or warp during temperature changes. Conforming to the profile of the dies 408 may include expanding or contracting individual areas of the flexible membrane 433 to maintain a thermal connection with an underlying die 408. The profile of the dies 408 may refer to the vertical profile or individual heights of the dies 408, which may change during thermal movement.

Some embodiments may also include a TIM 410 between the flexible membrane 433 and the tops of the dies 408. The TIM 410 is optional and may improve the thermal conductivity between the dies 408 and the flexible membrane 433 in some arrangements. The TIM 410 may be relatively thin compared to the cover 412 and/or the dies 408. Therefore, contacting the dies 408 with the TIM 410 may be functionally equivalent to contacting the tops of the dies 408 with the flexible membrane 433 itself, since the flexible membrane 433 and the TIM 410 will be expected to maintain contact with each other throughout thermal movement.

Since the flexible membrane 433 is configured to move with the dies 408 during thermal expansion, this allows for more efficient connections to be formed between the flexible membrane 433 and the dies 408. For example, instead of requiring a compressible/expandable TIM, the TIM 410 may instead be solid. In previous solutions, a solid TIM was not feasible since any movement would cause a separation between the TIM and the dies. Additionally, the flexible membrane 433 allows more permanent connections between the TIM 410 and the dies 408. Without the flexible membrane 433 a rigid connection between the TIM 410 and the dies 408 could result in cracking or damage to the components of the multi-die package 400 during thermal expansion. However, since the flexible membrane 433 moves with the dies 408 during thermal expansion, the TIM 410 can be more securely adhered to the dies 408 without causing damage. For example, the TIM 410 and/or flexible membrane 433 may be soldered or otherwise adhered to the tops of the dies 408. This more permanent connection between the TIM 410 or flexible membrane 433 and the dies 408 may better ensure that the flexible membrane 433 moves with the dies 408 during thermal expansion or contraction. For example, this connection may “pull” the flexible membrane down if a stack of dies were to move away from the cover 412.

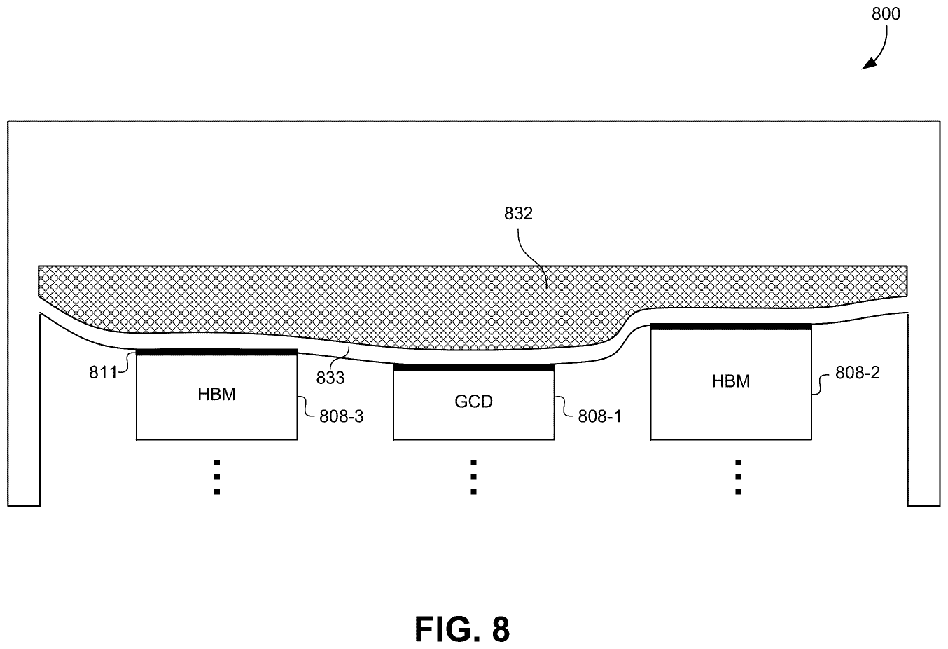

Note that pressurizing the liquid 432 is not required in all embodiments. The flexible membrane 433 may be sufficiently flexible that installing the cover 412 may cause the flexible membrane 433 to deform to match the profile of the dies 408. For example, as the cover 412 is installed, the flexible membrane 433 may be compressed against the die stacks and allowed to bulge between the die stacks. An example of this type of compression fit may be illustrated below in FIG. 8. This allows the pressure of the liquid 832 to be maintained around the atmospheric pressure instead of requiring a pressure above the surrounding atmospheric pressure to maintain contact with the dies 408.

These embodiments solve the problem of maintaining a thermally conductive connection between the dies 408 and a heatsink 418. As described above, a heatsink 418 may be formed as part of the cover 412 or may be thermally coupled to the cover 412 using a TIM or other adhesive, which are not shown explicitly in FIG. 4. Any heat generated by the dies 408 may be transmitted through the TIM 410 and into the cover 412 through the flexible membrane 433 and/or the liquid 432. The heat may then be conducted into the heatsink 418 and dissipated into the surrounding environment. The total thermal conductivity of this conductive pathway between the dies 408 and the heatsink 418 may be less than about 1° C./W, less than about 0.5° C./W, or less than about 0.1° C./W, depending on the particular embodiment.

It should be emphasized that traditional cold plates, lids, and other covers for integrated circuit dies have used flat, rigid, and smooth surfaces to interface with the dies 508. Since the tops of the dies 508 individually have flat surfaces, the flat surface of the bottom of the cover would create the best thermal interface since the bottom surface of the cover would not move. The embodiments described herein use a counterintuitive configuration that includes a thin flexible membrane that is allowed to move and flex in order to maintain contact with the dies as described above. Even though the tops of the individual dies may be flat and smooth, the profile of the dies collectively is not flat and level. The flexible membrane that conforms to this shifting profile of the dies creates a better thermal connection than the traditional flat smooth surfaces used on the bottom of the covers.

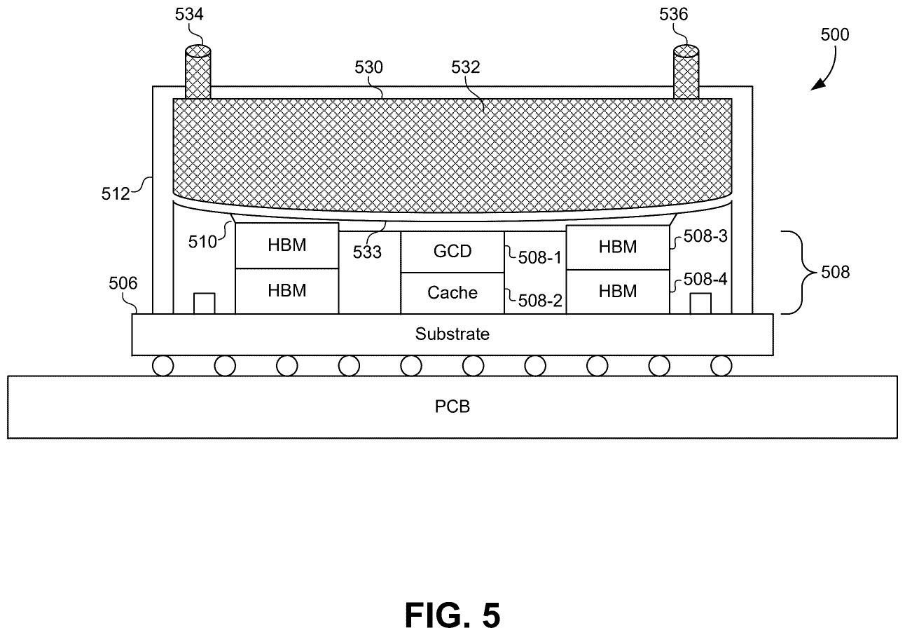

FIG. 5 illustrates a multi-die package 500 with a cover comprising a cold plate that interfaces with a liquid cooling system, according to some embodiments. As described above, different types of covers may be used in various configurations. Instead of using a lid with a flexible membrane, some embodiments may instead use a cover that allows for circulating liquid into the cover. This type of cover may be referred to as a cold plate 512. The cold plate 512 may include an internal cavity 530 that is filled with a liquid 532. These embodiments may include an inlet 534 and an outlet 536 through which the liquid 532 may be circulated. A central cooling system may pump the liquid 532 through the inlet 534 and the outlet 536 to circulate the liquid 532 through the cold plate 512. Instead of dissipating heat through a heatsink that is mounted to the cold plate 512, these embodiments may instead absorb heat into the liquid 532, which is then pumped out of the cold plate 512 and dissipated in the central cooling system.

This multi-die package 500 may operate in a similar fashion as described above for the multi-die package 400 of FIG. 4. Although the internal cavity 530 may be larger to accommodate the flow of the liquid 532, the bottom of the cold plate 512 may include a flexible membrane 533 as described above. The pressure of the liquid 532 may be sufficient to cause the flexible membrane 533 to flex downward towards the dies 508 mounted to the substrate 506. The flexible membrane 533 may deform to conform to the profile of the dies 508 as the dies move due to thermal changes. As described above, the system may include a TIM 510, which may be solid and/or adhered to the tops of the dies 508. The flexible membrane 533 may be formed using any of the materials or configurations described above in FIG. 4.

In some embodiments, the pressure of the liquid 532 may be adjustable by the central cooling system in order to adjust the pressure within the internal cavity 530. Increasing the pressure may cause the flexible membrane 533 to expand further downward against the tops of the dies 508. Increasing the pressure may therefore create a better thermal contact between the flexible membrane 533 and the dies 508. The pressure of the liquid 532 in this and any other embodiments may be greater than the surrounding atmospheric pressure. For example, the pressure may be more than 5 PSI above the surrounding atmospheric pressure, more than 10 PSI above the surrounding atmospheric pressure, more than 15 PSI above the surrounding atmospheric pressure, more than 20 PSI above the surrounding atmospheric pressure, more than 30 PSI above the surrounding atmospheric pressure, more than 50 PSI above the surrounding atmospheric pressure, more than 75 PSI above the surrounding atmospheric pressure, or more than 100 PSI above the surrounding atmospheric pressure. The PSI may also include any range of values included in the values above (e.g., between about 25 PSI and about 75 psi above the surrounding atmospheric pressure).

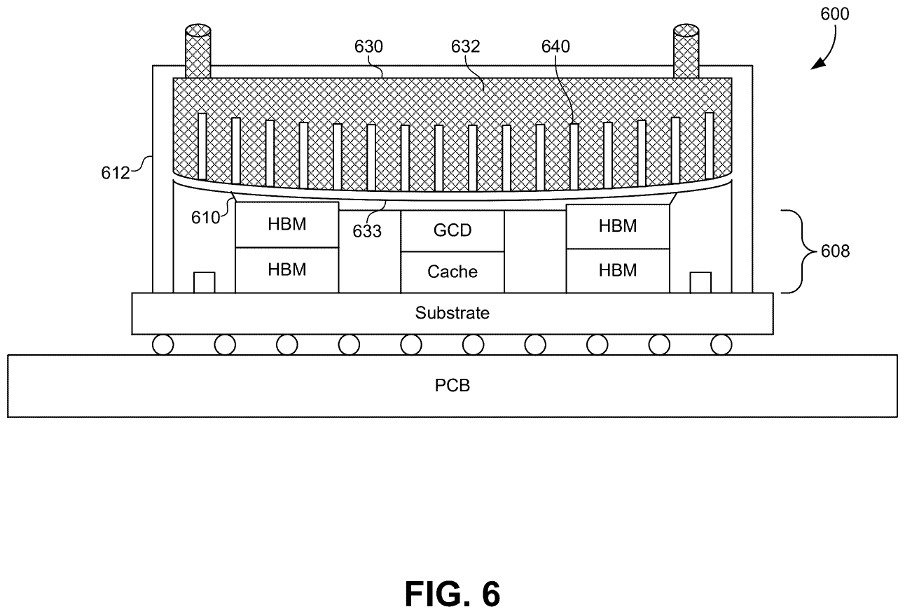

FIG. 6 illustrates a plurality of fins mounted on the flexible membrane to improve heat dissipation, according to some embodiments. This multi-die package 600 may include a flexible membrane 633 on the bottom of the cover 612 as described above. Additionally, fins 640 may be connected to the flexible membrane 633. The fins 640 may be formed from a solid material and may be integrally formed or attached to the top side of the flexible membrane 633. The fins 640 may include ridges, poles, posts, or any other type of protrusion or geometry that extends upwards from the flexible membrane 633 into the internal cavity 630. The fins 640 may be formed using any thermally conductive material, such as aluminum, copper, or other metals. In some embodiments, the fins 640 may be formed using the same material as the flexible membrane 633, such as carbon fiber.

The height and thickness of the fins 640 may vary. The height of the fins may be characterized as extending into the internal cavity 630 as a percentage of the height of the internal cavity 630. For example, the fins 640 may extend between about 10% about 25% of a height of the internal cavity 630, between about 25% and about 35%, between about 35% and about 50%, between about 50% and about 75%, and/or between about 75% and about 85% of the height of the internal cavity 630.

The fins 640 may serve to better dissipate heat from the flexible membrane 633 into the liquid 632. For example, heat absorbed by the flexible membrane 633 from the TIM 610 and/or the top surfaces of the dies 608 may be conducted into the fins 640. The heat may then be distributed from the fins 640 more evenly into the surrounding liquid 632. Note that the fins 640 are shown as part of a cold plate configuration as illustrated in FIG. 5. However, the fins 640 may also be used in the lid configuration of FIG. 4 or any other configuration using a flexible membrane.

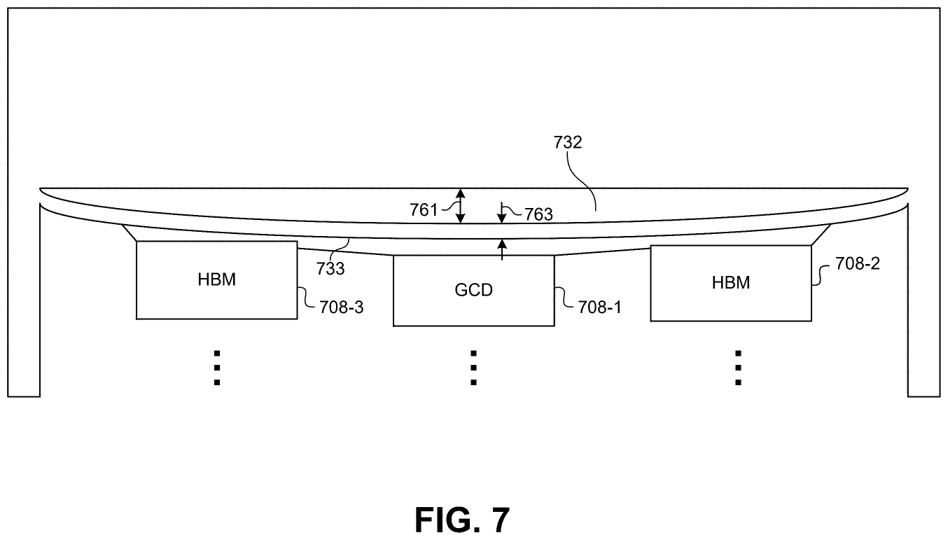

FIG. 7 illustrates a magnified view of the flexible membrane, according to some embodiments. Generally, the flexible membrane 733 should be relatively thin to allow for the necessary movement and flex described above. For example, the flexible membrane 733 may have a thickness 763 of between about 10 μm and about 20 μm, between about 20 μm and about 30 μm, between about 30 μm and about 40 μm, and/or between about 40 μm and about 50 μm. The thickness 763 may also be any combination of the ranges disclosed above (e.g., between about 20 μm and about 40 μm).

The flexible membrane 733 may be defined as “flexible” in comparison to the traditional rigid, smooth, inflexible surfaces of existing covers in that the flexible membrane 733 is allowed to flex downward under an internal PSI of between about 5 PSI to about 100 psi greater than the surrounding atmospheric pressure. The flexibility of the flexible membrane 733 may also be characterized by a flex or displacement distance at a center of the flexible membrane 733 when under these internal pressures. For example, the flexible membrane 733 may flex or be displaced to a distance 761 of between about 50 μm and about 75 μm, between about 75 μm and about 100 μm, between about hundred microns and about 150 μm, between about 150 μm and about 200 μm, and/or between about 200 μm and about 250 μm. The distance 761 may also be any combination of the ranges disclosed above (e.g., between about 100 μm and about 200 μm). The flexible membrane 733 may also be characterized by a difference between the relative heights of the vertical stacks of the dies 708. For example, the flexible membrane 733 may be characterized as able to flex enough to maintain contact with a difference in height between the individual dies 708-1, 708-2, 708-3 of between about 50 μm and about 200 μm.

FIG. 8 illustrates a magnified view of the flexible membrane as it deforms to conform to the profile of the dies, according to some embodiments. This view shows how the different heights of the dies 808-1, 808-2, 808-3 may be accommodated by the flexible membrane 833. These height differences may result from different manufacturing tolerances and/or from thermal expansion/contraction during temperature changes. An adhesive 811 may optionally bonded the flexible membrane 833 to the dies 808. The adhesive 811 may also include a solid or flexible TIM as described above. The shape of the flexible membrane 833 may deform as needed to conform to the profile of the dies 808 and maintain a thermally conductive coupling to the dies 808. This deformation formation may be caused by the pressure of the liquid 832 pressing against the flexible membrane 833. This deformation may also be caused by the adhesive 811 causing the flexible membrane 833 to maintain contact with the tops of the dies 808 and “pull” the flexible membrane 833 with the dies as they move up, down, and/or laterally.

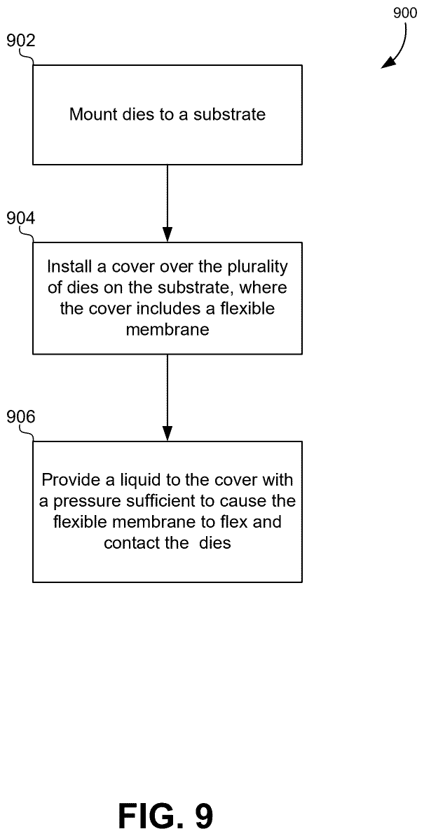

FIG. 9 illustrates a method of assembling a multi-die package, according to some embodiments. This method may be performed during an assembly of the individual parts into the multi-die package as described relative to any of the figures above. The method may include mounting a plurality of dies to a substrate (902). As described above, the plurality of dies may be mounted within a footprint of a cover, such as a lid or cold plate to be placed above the plurality of dies. The dies may be mounted in a vertical configuration with multiple dies stacked on top of each other. The dies may be mounted to a substrate, which in turn may be mounted to a PCB that may interface with other multi-die packages or other external systems.

The method may also include installing a cover over the plurality of dies on the substrate, wherein the cover comprises a flexible membrane (904). The cover may be mounted to the substrate and may enclose the plurality of dies. The cover may include any of the configurations described above, such as a lid as shown in FIG. 4, a cold plate as shown in FIG. 5, or any other type of cover configuration. The bottom surface of the cover may include a flexible membrane that is configured to deform to conform to the profile of the dies. The flexible membrane may form an internal cavity between the flexible membrane and the solid body or top of the cover, depending on the configuration. Optionally, a heatsink may be mounted to the cover, and a TIM may be applied between the dies and the flexible membrane as described above.

The method may further include providing a liquid to an internal cavity of the cover (906). For example, a pressurized liquid may be provided to the internal cavity between the flexible membrane and the body or top surface of the cover. The liquid may include a liquid metal or any of the other materials described above. The liquid may have a pressure sufficient to cause the flexible membrane to flex and contact the plurality of dies. For example, the cover may be a cold plate that includes an inlet and an outlet for circulating the pressurized liquid from a liquid cooling system. Alternatively, the liquid may be statically enclosed in the internal cavity as illustrated in FIG. for 4, such that the liquid does not circulate out of the cavity. The liquid may be pressurized at or above the surrounding atmospheric pressure as needed to maintain contact with the dies during thermal movement.

In some embodiments, a controller may be configured to dynamically control the pressure of the liquid. Therefore, the pressure of the liquid may be dynamically adjustable to cause the flexible membrane to flex and contact the plurality of dies as needed. For example, a controller of a central cooling system may be configured to control a pressure of the liquid being pumped into the cover. The pressure of the liquid may be increased or decreased as needed to ensure contact between the flexible membrane and the dies. For example, a temperature sensor may be used to detect heat buildup within the cover around the dies. If the heat becomes excessive, the pressure of the liquid may be increased to more rapidly circulate liquid through the cover and to further deform or “push” the flexible membrane against the top of the dies to maintain an efficient thermal connection. The controller may include a system controller that includes one or more processors that execute instructions stored on one or more non-transitory computer-readable media.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A die package comprising:
a substrate;
a plurality of dies mounted to the substrate; and
a cover placed over the plurality of dies on the substrate, wherein the cover comprises a flexible membrane configured to deform to conform to a profile of the plurality of dies when placed over the plurality of dies.

2. The die package of claim 1, wherein the cover comprises a lid that is mounted to the substrate and covers the plurality of dies on the substrate, and the flexible membrane is located on a bottom surface of the cover adjacent to the plurality of dies.

3. The die package of claim 1, wherein the cover comprises a heatsink that is an integrated part of the cover or is thermally coupled to the cover to dissipate heat absorbed by the cover from the plurality of dies.

4. The die package of claim 1, wherein the plurality of dies are adhered to the flexible membrane using an adhesive, such that when the plurality of dies or the cover expands or contracts due to temperature changes, the flexible membrane remains in contact with the plurality of dies through the adhesive.

5. The die package of claim 1, wherein the plurality of dies are mounted to the substrate such that the plurality of dies are not all a same height from the substrate.

6. The die package of claim 1, wherein the flexible membrane is configured to flex at least 200 μm at a center of the flexible membrane.

7. The die package of claim 1, wherein the flexible membrane has a thickness of between 10 μm and 50 μm.

8. The die package of claim 1, wherein the cover comprises an internal cavity that is filled with liquid, wherein the liquid is pressurized to cause the flexible membrane to deform to conform to the profile of the plurality of dies.

9. The die package of claim 8, wherein the liquid comprises a liquid metal.

10. A die package comprising:
a substrate;
a plurality of dies mounted to the substrate; and
a cold plate that interfaces with a liquid cooling system, wherein the liquid cooling system is configured to pump a pressurized liquid through the cold plate, the cold plate comprises a flexible membrane, and the pressurized liquid causes the flexible membrane to deform to contact the plurality of dies when the cold plate is installed above the plurality of dies.

11. The die package of claim 10, wherein the cold plate further comprises an inlet and an outlet for circulating the pressurized liquid from the liquid cooling system.

12. The die package of claim 10, wherein the flexible membrane is formed from carbon fiber.

13. The die package of claim 10, wherein the flexible membrane is formed from aluminum.

14. The die package of claim 10, wherein the cold plate comprises an internal cavity, and the internal cavity comprises a plurality of fins mounted on the flexible membrane extending away from the flexible membrane into the internal cavity.

15. The die package of claim 10, wherein the pressurized liquid causes the flexible membrane to be displaced at least 100 μm at a center of the flexible membrane.

16. A method of assembling a die package, the method comprising:
mounting a plurality of dies to a substrate;
installing a cover over the plurality of dies on the substrate, wherein the cover comprises a flexible membrane; and
providing a liquid to the cover, wherein the liquid has a pressure sufficient to cause the flexible membrane to flex and contact the plurality of dies.

17. The method of claim 16, wherein the liquid is provided by a liquid cooling system by circulating the liquid through an inlet and an outlet in the cover, and the pressure of the liquid is adjustable to cause the flexible membrane to flex and contact the plurality of dies.

18. The method of claim 16, wherein the liquid is statically enclosed in an internal cavity of the cover, and the liquid comprises a liquid metal.

19. The method of claim 16, further comprising mounting a heatsink to the cover and mounting the substrate to a printed circuit board.

20. The method of claim 16, wherein the liquid is pressurized at or above a surrounding atmospheric pressure.
